(19) United States
(12) Patent Application Publication
(10) Pub. No.: US 2026/0150618 A1
(43) Pub. Date: May 28, 2026

(54) SUBSTRATE STORAGE CONTAINER AND LID THEREOF

(71) Applicant: MIRAIAL CO., LTD., Tokyo (JP)

(72) Inventors: Ryuuji FUKUDA, Tokyo (JP); Takuto SHIKA, Tokyo (JP)

(21) Appl. No.: 19/099,924

(22) PCT Filed: Aug. 4, 2022
(86) PCT No.: PCT/JP2022/029883

§ 371 Date: Jan. 30, 2025

(51) Int. Cl. H10P 72/10

(52) U.S. Cl. CPC H10P 72/1916; H10P 72/1921

(57) ABSTRACT

A substrate storage container includes a container body and a lid having a seal member attachment portion and a periphery portion-opposing portion opposing the opening periphery portion. The lid further has a seal member attached to the seal member attachment portion. The seal member is interposed between the opening periphery portion and the periphery portion-opposing portion, and tightly abuts on the opening periphery portion and the periphery portion-opposing portion, thereby closing the container body opening portion. The seal member includes a base portion held by the seal member attachment portion; a periphery portion-abutting lip portion extending from the base portion and abutting on the opening periphery portion; and an opposing portion-abutting lip portion extending from the base portion and abutting on the periphery portion-opposing portion. The periphery portion-opposing portion has a cross-sectional shape indicating a placement target PT and not being a direct flat plane.

### TECHNICAL FIELD

The present invention relates to a substrate storing container that stores substrates such as semiconductor wafers, and a lid of the substrate storing container.

### BACKGROUND ART

As a container that stores substrates such as semiconductor wafers, a substrate storing container, having a container main body and a lid, has been known conventionally.

The container main body includes a tubular wall having a container main body opening formed at one end thereof and having the other end closed. The container main body has a substrate storing space formed therein. The substrate storing space is formed by being surrounded by the wall and can store a plurality of substrates. The lid is attachable to and detachable from the container main body opening and can close the container main body opening.

A front retainer is provided at a part of the lid that faces a substrate storing space when the container main body opening is closed with the lid. The front retainer can support edge portions of the plurality of substrates when the container main body opening is closed with the lid. Furthermore, a back-side substrate support portion is provided at the wall so as to form a counterpart to the front retainer. The back-side substrate support portion can support edge portions of the plurality of substrates. When the container main body opening is closed with the lid, the back-side substrate support portion retains, in cooperation with the front retainer, the plurality of substrates in a state in which the adjacent substrates are arranged in parallel and spaced apart from each other by a predetermined interval.

The lid is provided with a sealing member. The sealing member is attached to a sealing member attachment portion of the lid and extends all along an outer rim portion of the lid. In a state in which the lid is attached to an opening rim portion of the opening, the sealing member is elastically deformed by being held between a sealing face of the container main body and the inner surface of the lid, and the lid hermetically closes the container main body opening. By removing the lid from the opening rim portion, the substrates can be loaded into and unloaded from the substrate storing space of the container main body (see, for example Patent Document 1).

### CITATION LIST

### Patent Document

Patent Document 1: Japanese Patent No. 4953690

### DISCLOSURE OF THE INVENTION

### Problems to be Solved by the Invention

In order to ensure airtightness during the closure with the sealing member, the sealing member needs to be appropriately attached to the sealing member attachment portion of the lid and be disposed at a target position set for the sealing member. However, it is not easy to dispose the sealing member at the target position.

An object of the present invention is to provide a substrate storing container that allows a sealing member to be appropriately attached to a sealing member attachment portion of a lid and to be easily disposed at a target position. Another object of the present invention is to provide such a lid.

### Means for Solving the Problems

The present invention relates to a substrate storing container including: a container main body having therein a substrate storing space that is capable of storing a plurality of substrates, and having, at one end thereof, an opening rim portion that defines a container main body opening communicating with the substrate storing space; and a lid attachable to and detachable from the container main body opening, capable of closing the container main body opening, and including a sealing member attachment portion and a rim portion facing portion that faces the opening rim portion. The lid further includes a sealing member that is attached to the sealing member attachment portion of the lid and lies between the opening rim portion and the rim portion facing portion to come into tight contact therewith, so that the sealing member airtightly closes the container main body opening. The sealing member includes: a base portion that is retained by the sealing member attachment portion; a rim-portion-abutting lip portion that extends from the base portion and abuts on the opening rim portion, and a facing-portion-abutting lip portion that extends from the base portion and abuts on the rim portion facing portion. The rim portion facing portion has a cross-sectional shape that is not of a straightly flat plane and indicates a target position for the facing-portion-abutting lip portion.

Preferably, the cross-sectional shape that is not of a straightly flat plane of the rim portion facing portion may be a protruding shape that protrudes toward the facing-portion-abutting lip portion with respect to the straightly flat plane serving as a reference.

Preferably, the protruding shape of the rim portion facing portion may be a smoothly protruding shape, a shape in which a plurality of straightly flat planes are connected to each other, or a shape having a projection that locally projects so as to be able to restrict a movement of the facing-portion-abutting lip portion.

Preferably, the cross-sectional shape that is not of a straightly flat plane of the rim portion facing portion may have a restricting concavity that caves in to be away from the facing-portion-abutting lip portion with respect to the straightly flat plane serving as a reference, and that is engageable with the facing-portion-abutting lip portion.

Preferably, the rim portion facing portion may have the cross-sectional shape that is not of a straightly flat plane all along a rim portion of the lid.

The present invention also relates to a lid of a substrate storing container. The substrate storing container includes a container main body having therein a substrate storing space that is capable of storing a plurality of substrates, the container main body having, at one end thereof, an opening rim portion that defines a container main body opening communicating with the substrate storing space. The lid is attachable to and detachable from the container main body opening. The lid includes: a sealing member attachment portion and a rim portion facing portion that faces the opening rim portion, so that the lid is capable of closing the container main body opening; a sealing member that is attached to the sealing member attachment portion of the lid and lies between the opening rim portion and the rim portion facing portion to come into tight contact therewith, so that the sealing member airtightly closes the container main body opening. The sealing member includes a base portion that is retained by the sealing member attachment portion, a rim-portion-abutting lip portion that extends from the base portion and abuts on the opening rim portion, and a facing-portion-abutting lip portion that extends from the base portion and abuts on the rim portion facing portion. The rim portion facing portion has a cross-sectional shape that is not of a straightly flat plane and indicates a target position for the facing-portion-abutting lip portion.

### Effects of the Invention

The present invention can provide a substrate storing container that allows the sealing member to be appropriately attached to the sealing member attachment portion of the lid and to be easily disposed at the target position and a lid to be used therewith.

### BRIEF DESCRIPTION OF THE DRAWINGS

FIG. 1 is an exploded perspective view illustrating a substrate storing container 1 according to a first embodiment of the present invention;

FIG. 2 is an exploded perspective view illustrating a state in which substrates W are stored in the substrate storing container 1 according to the first embodiment of the present invention;

FIG. 3 is a perspective view of a lid 3 of the substrate storing container 1 according to the first embodiment of the present invention, and illustrates a state in which the lid 3 has a sealing member 4 and a front retainer 7 attached thereto;

FIG. 4 is a perspective view illustrating the sealing member 4 of the lid 3 of the substrate storing container 1 according to the first embodiment of the present invention;

FIG. 5 is a rear view of the lid 3 of the substrate storing container 1 according to the first embodiment of the present invention, and illustrates a state in which the lid 3 has the sealing member 4 and the front retainer 7 removed;

FIG. 6A is a cross-sectional view taken along line A-A in FIGS. 3 and 5;

FIG. 6B is an enlarged view of a part of FIG. 6A;

FIG. 6C is a diagram illustrating a state in which the sealing member 4 is deviated from a target position, in comparison with FIG. 6A;

FIG. 7A is a cross-sectional view (corresponding to FIG. 6A) illustrating a lid 3 of a substrate storing container 1 according to a second embodiment of the present invention;

FIG. 7B is an enlarged view of a part of FIG. 7A;

FIG. 8 is a cross-sectional view (corresponding to FIG. 6A) illustrating a lid 3 of a substrate storing container 1 according to a third embodiment of the present invention;

FIG. 9 is a cross-sectional view (corresponding to FIG. 6A) illustrating a lid 3 of a substrate storing container 1 according to a fourth embodiment of the present invention;

FIG. 10A is a plan view illustrating a substrate holding adapter 8;

FIG. 10B is a plan view illustrating a state in which a substrate W is held on the substrate holding adapter 8; and

FIG. 10C is a schematic longitudinal cross-sectional view taken along the centerline of FIG. 10B.

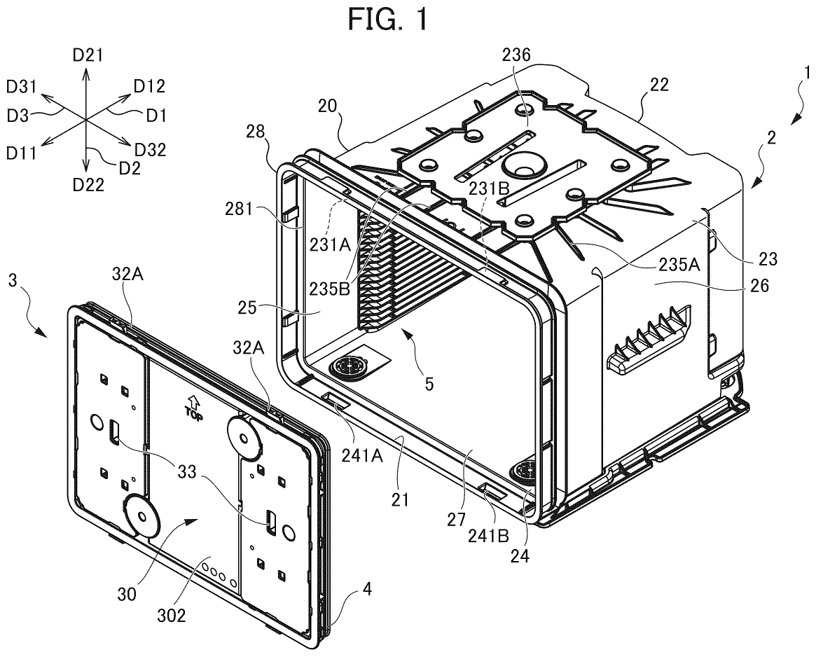

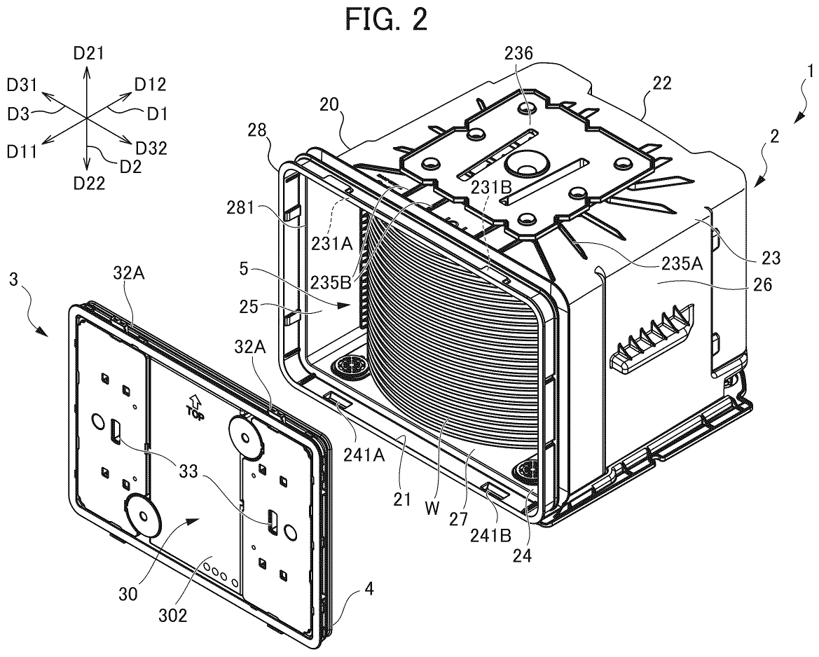

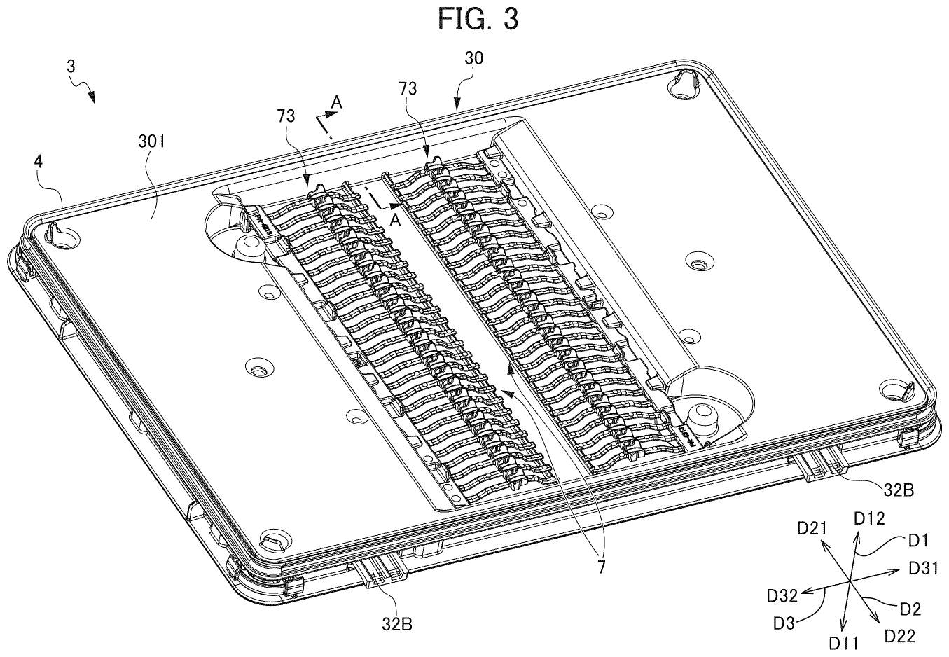

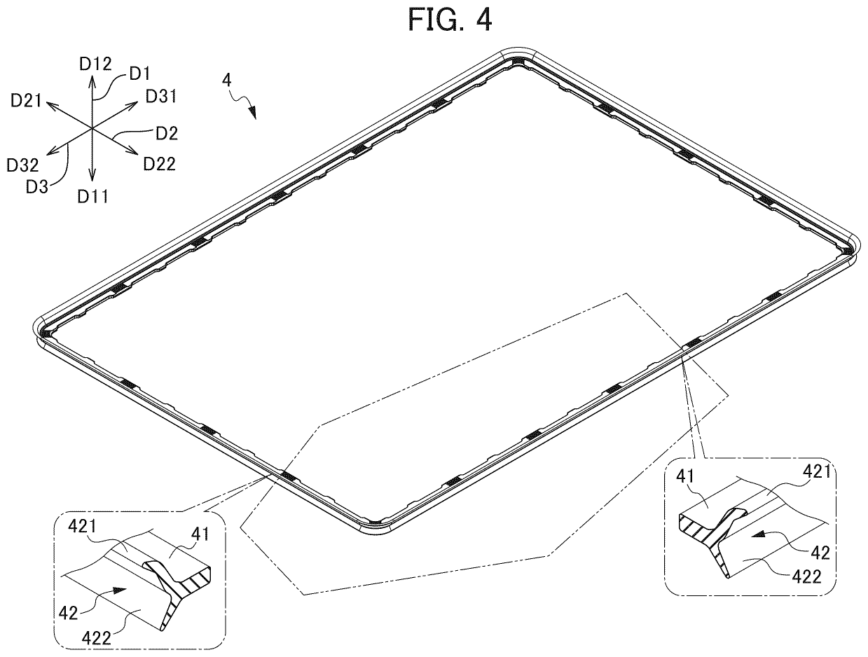

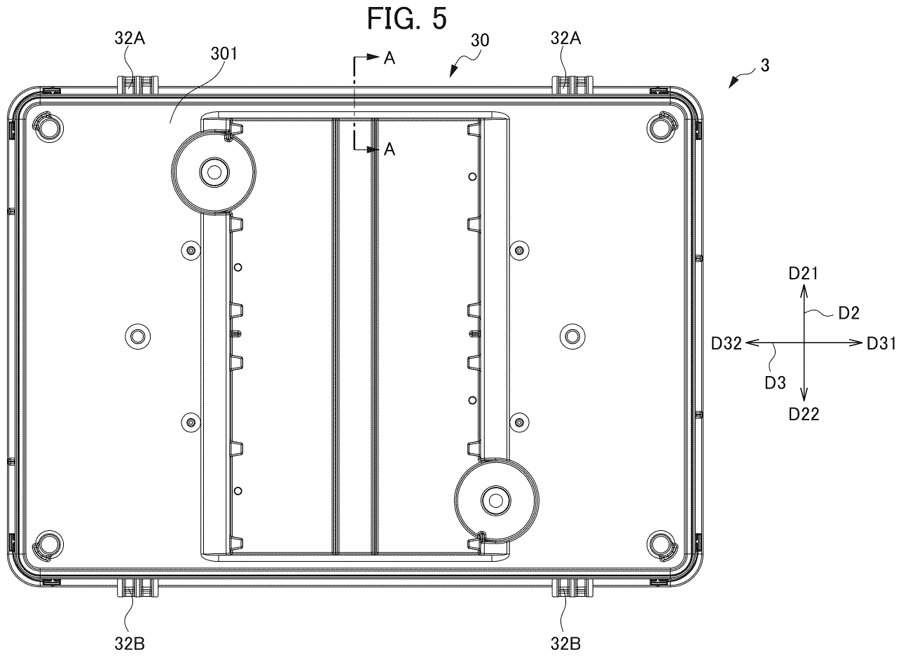

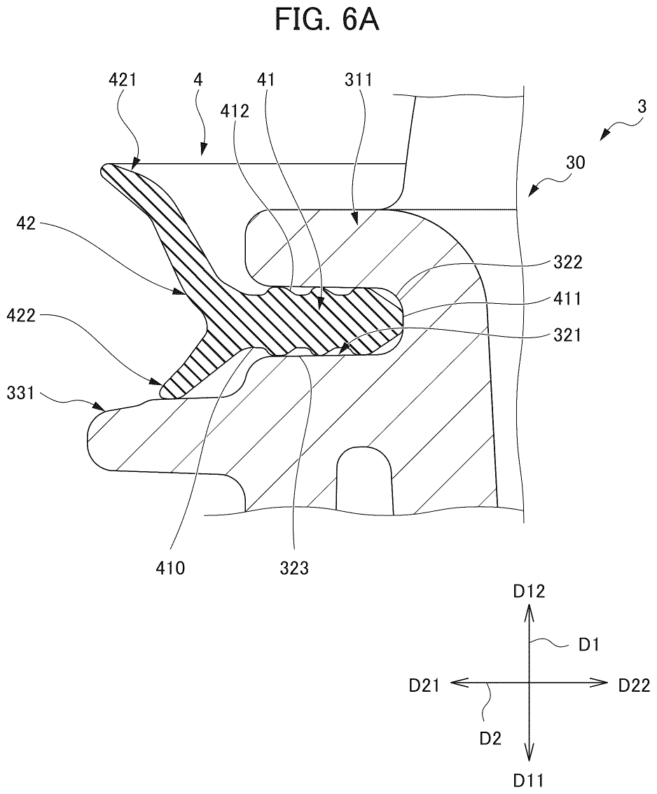

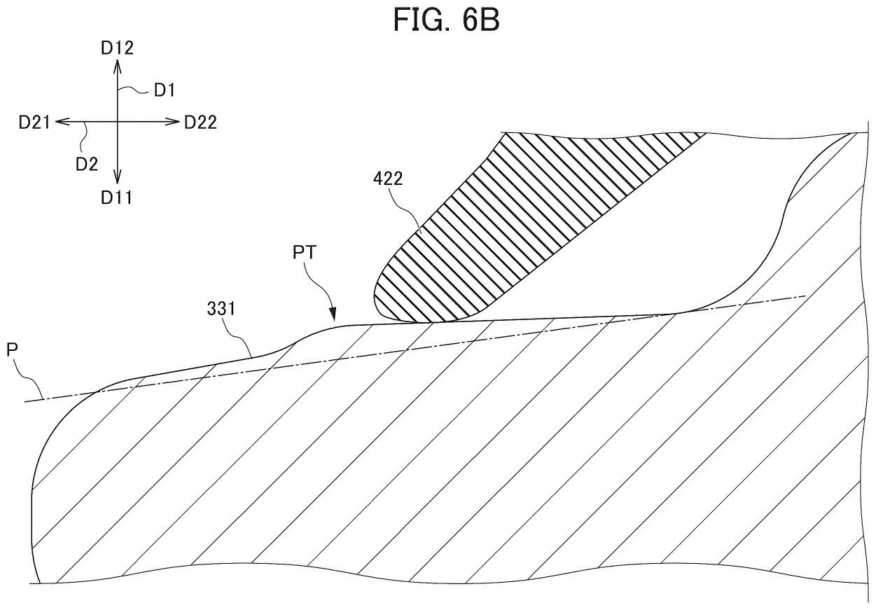

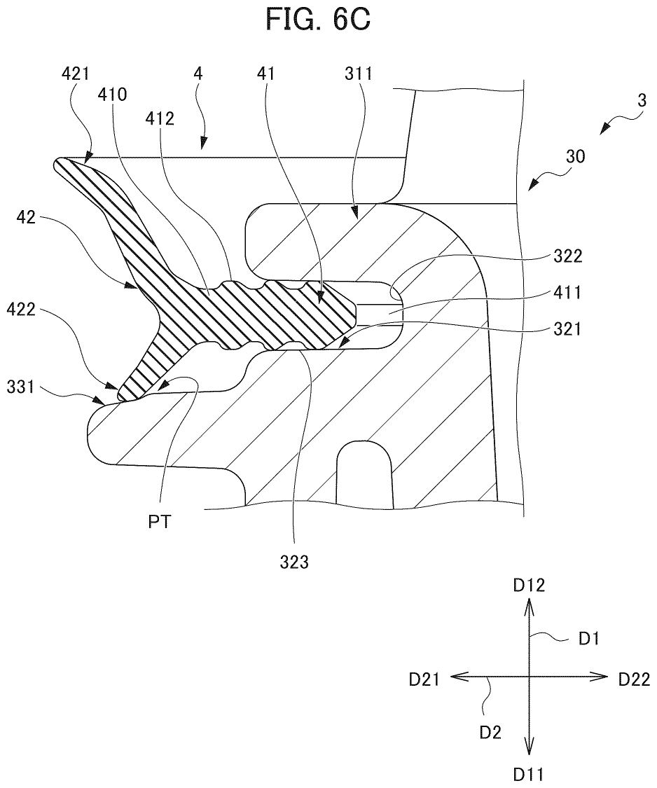

### PREFERRED MODE FOR CARRYING OUT THE INVENTION

[First Embodiment]a substrate storing container 1 according to a first embodiment of the present invention will be described below with reference to the drawings. FIG. 1 is an exploded perspective view illustrating the substrate storing container 1 according to the first embodiment of the present invention. FIG. 2 is an exploded perspective view illustrating a state in which substrates W are stored in the substrate storing container 1 according to the first embodiment of the present invention. FIG. 3 is a perspective view of a lid 3 of the substrate storing container 1 according to the first embodiment of the present invention, and illustrates a state in which the lid 3 has a sealing member 4 and a front retainer 7 attached thereto; FIG. 4 is a perspective view illustrating the sealing member 4 of the lid 3 of the substrate storing container 1 according to the first embodiment of the present invention. FIG. 5 is a rear view of the lid 3 of the substrate storing container 1 according to the first embodiment of the present invention, and illustrates a state in which the lid 3 has the sealing member 4 and the front retainer 7 removed therefrom. FIG. 6A is a cross-sectional view taken along line A-A in FIGS. 3 and 5. FIG. 6B is an enlarged view of a part of FIG. 6A. FIG. 6C is a diagram illustrating a state in which the sealing member 4 is deviated from a target position, in comparison with FIG. 6A.

Herein, for convenience of explanation, the direction from a container main body 2 toward the lid 3 (described later) (a direction from upper right to lower left in FIG. 1) is defined as a forward direction D11, and the direction opposite to the direction D11 is defined as a backward direction D12. Furthermore, these directions are defined as a forward/backward direction D1. In addition, the direction from a lower wall 24 to an upper wall 23 (described later) (upper direction in FIG. 1) is defined as an upward direction D21, and the direction opposite to the direction D21 is defined as a downward direction D22. Furthermore, these directions are defined as an upward/downward direction D2. Moreover, the direction from a second side wall 26 to a first side wall 25 (described later) (a direction from lower right to upper left in FIG. 1) is defined as a left direction D31, and the direction opposite to the direction D31 is defined as a right direction D32. Furthermore, these directions are defined as a left/right direction D3.

The substrates W (see FIG. 2) stored in the substrate storing container 1 are thin substrates for industrial use, and examples thereof include disk-shaped silicon wafers, disk-shaped glass wafers, and disk-shaped sapphire wafers. Each substrate W of the present embodiment is a silicon wafer having a diameter of 200 mm to 450 mm.

As illustrated in FIGS. 1 and 2, the substrate storing container 1 is for storing the substrates W each made of the silicon wafer described above, and includes a container main body 2, a lid 3, substrate support plate-like portions 5 as a side substrate support, a back-side substrate support portion (not shown), and a front retainer 7 as a lid-side substrate support.

As illustrated in FIG. 1, the container main body 2 includes a tubular wall 20 having a container main body opening 21 formed at one end thereof and having the other end closed. The container main body 2 has a substrate storing space 27 formed therein. The substrate storing space 27 is surrounded and defined by the wall 20. The substrate support plate-like portions 5 are disposed on portions of the wall 20 that define the substrate storing space 27. As illustrated in FIG. 2, the substrate storing space 27 can store therein the plurality of substrates W.

The substrate support plate-like portions 5 are provided on the wall 20 so as to form counterparts to each other in the left/right direction D3 in the substrate storing space 27. When the container main body opening 21 is not closed with the lid 3, the substrate support plate-like portions 5 can support side portions of edge portions of the plurality of substrates W by contacting with the side portions of the edge portions of the plurality of substrates W in a state in which adjacent substrates W are arranged in parallel with and spaced apart from each other by a predetermined interval. The back-side substrate support portion (not shown) is provided on the back side of the substrate support plate-like portions 5.

The back-side substrate support portion (not shown) is provided on the wall 20 so as to form a counterpart to the front retainer 7 in the substrate storing space 27. The back-side substrate support portion (not shown) can support rear portions of the edge portions of the plurality of substrates W by contacting with the rear portions of the edge portions of the plurality of substrates W when the container main body opening 21 is closed with the lid 3.

The lid 3 is attachable to and detachable from an opening rim portion 28 that defines the container main body opening 21, and can close the container main body opening 21. The front retainer 7 is provided on a portion of the lid 3 that faces the substrate storing space 27 when the container main body opening 21 is closed with the lid 3. The front retainer 7 is disposed so as to form a counterpart to the back-side substrate support portion in the forward/backward direction D1 in the substrate storing space 27.

When the container main body opening 21 is closed with the lid 3, the front retainer 7 can support front portions of the edge portions of the plurality of substrates W by contacting with the edge portions of the plurality of substrates W. When the container main body opening 21 is closed with the lid 3, the front retainer 7 cooperates with the back-side substrate support portion (not shown) to hold the plurality of substrates W in a state in which the adjacent substrates W are arranged in parallel with and spaced apart from each other by a predetermined interval. Hereinafter, each component will be described in detail.

As illustrated in FIG. 1, etc., the wall 20 of the container main body 2 includes a back wall 22, an upper wall 23, a lower wall 24, a first side wall 25, and a second side wall 26. The back wall 22, the upper wall 23, the lower wall 24, the first side wall 25, and the second side wall 26 can be made of a plastic material, etc., and are configured as a one-piece molding of polycarbonate in the present embodiment.

The first side wall 25 faces the second side wall 26, and the upper wall 23 faces the lower wall 24. A rear end of the upper wall 23, a rear end of the lower wall 24, a rear end of the first side wall 25, and a rear end of the second side wall 26 are all connected to the back wall 22. A front end of the upper wall 23, a front end of the lower wall 24, a front end of the first side wall 25, and a front end of the second side wall 26 each have a positional relationship of being opposite to the back wall 22, and configure the opening rim portion 28 that defines the container main body opening 21 having substantially rectangular shape.

The opening rim portion 28 is provided at one end of the container main body 2, and the back wall 22 is located at the other end of the container main body 2. The outer shape of the container main body 2 formed with the outer surface of the wall 20 is a box shape. The inner surface of the wall 20, that is, the inner surface of the back wall 22, the inner surface of the upper wall 23, the inner surface of the lower wall 24, the inner surface of the first side wall 25, and the inner surface of the second side wall 26 surround and define the substrate storing space 27. The container main body opening 21 defined by the opening rim portion 28 communicates with the substrate storing space 27 that is surrounded with the wall 20 and formed in the container main body 2. The substrate storing space 27 can store a maximum of twenty-five substrates W.

As illustrated in FIGS. 1 and 2, latch engagement concave portions 231A, 231B, 241A, and 241B, which are concave outwardly from the substrate storing space 27, are formed at portions of the upper wall 23 and the lower wall 24 which are proximal to the opening rim portion 28. A total of four latch engagement concave portions 231A, 231B, 241A, and 241B are formed in proximity to the left and right ends of the upper wall 23 and the left and right ends of the lower wall 24, on a one-to-one basis.

As illustrated in FIGS. 1 and 2, a flange fixing portion (not illustrated) and ribs 235A and 235B are integrally formed with the upper wall 23 at an outer surface of the upper wall 23. The flange fixing portion (not illustrated) is disposed at a center portion of the upper wall 23. A top flange 236 is fixed at the flange fixing portion (not illustrated). The top flange 236 is disposed at the center portion of the upper wall 23. The top flange 236 is a member by means of which the substrate storing container 1 is hooked and hung in an automated wafer transport system (e.g., an AMHS), a wafer substrate transport cart (e.g., a PGV), or the like.

The ribs 235A extend in the plural manner substantially in the left direction and the right direction respectively from the top flange 236. The ribs 235B extend in the plural manner in the forward direction D11 and the backward direction D12 respectively from the top flange 236.

The lid 3 is provided with a latch mechanism. The latch mechanism is provided in proximity to the left and right ends of the lid 3. As illustrated in FIGS. 1 to 3 and 5, the latch mechanism includes two upper latch parts 32A that can protrude from the upper side of the lid 3 in the upward direction D21, and two lower latch parts 32B that can protrude from the lower side of the lid 3 in the downward direction D22. The two upper latch parts 32A are disposed respectively in proximity to the left and right ends of the upper side of the lid 3, and the two lower latch parts 32B are disposed respectively in proximity to the left and right ends of the lower side of the lid 3.

The outer surface of the lid 3 is provided with operation parts 33. Operating the operation parts 33 from the front side of the lid 3 causes the upper latch parts 32A and the lower latch parts 32B: to protrude respectively from the upper side and the lower side of the lid 3; and not to protrude respectively from the upper side and the lower side of the lid 3. The upper latch parts 32A protrude from the upper side of the lid 3 in the upward direction D21 to engage with the latch engagement concave portions 231A, 231B of the container main body 2, and the lower latch parts 32B protrude from the lower side of the lid 3 in the downward direction D22 to engage with the latch engagement concave portions 241A, 241B of the container main body 2, whereby the lid 3 is fastened to the opening rim portion 28 of the container main body 2.

The front retainer 7 is fixed to the inner side of the lid main body 30 of the lid 3. In the present embodiment, the front retainer 7 is composed of parts separate from each other in the left/right direction D3. The front retainer 7 has front-retainer substrate receiving portions 73. Two front-retainer substrate receiving portions 73 are arranged in each row to be an aligned pair spaced apart from each other in the left/right direction D3 by a predetermined distance. The front-retainer substrate receiving portions 73 in which adjacent two are arranged in a pair aligned as described above include twenty-five pairs in parallel in the upward/downward direction D2. When the substrates W are stored in the substrate storing space 27 and the lid 3 is closed, the front-retainer substrate receiving portions 73 hold ends of the edge portions of the substrates W therebetween.

As illustrated in FIGS. 3 to 5, the lid 3 has a substantially rectangular shape that coincides substantially with the shape of the opening rim portion 28 of the container main body 2. The lid 3 is attachable to and detachable from the opening rim portion 28 of the container main body 2 2. By attaching the lid 3 to the opening rim portion 28, the container main body opening 21 can be closed with the lid 3. A sealing member 4 having a loop shape is attached to a surface of an inner surface of the lid 3 (the back-side surface of the lid 3 illustrated in FIG. 1) that faces a step portion (sealing face 281) formed at a location in the immediate rear of the opening rim portion 28 in the backward direction D12, when the lid 3 closes the container main body opening 21.

The sealing member 4 includes a lip portion 42 (to be described later). When the lid 3 is attached to the opening rim portion 28, the lip portion 42 is elastically deformed by being sandwiched between the sealing face 281 and a rim portion facing portion 331 that forms part of the inner surface of the lid 3, and the lid 3 hermetically closes the container main body opening 21. By removing the lid 3 from the opening rim portion 28, the substrates W can be loaded into and unloaded from the substrate storing space 27 of the container main body 2.

More specifically, the lid 3 includes the lid main body 30. The lid main body 30 constitutes the contour of the lid 3 having a substantially rectangular shape. Thus, the lid main body 30 has a substantially rectangular shape. The lid main body 30 includes an inner surface 301 (refer to FIG. 3, etc.) and an outer surface 302. The inner surface 301 faces the substrate storing space 27 when the container main body opening 21 is closed with the lid 3. The outer surface 302 is exposed to the outside of the substrate storing container 1 when the container main body opening 21 is closed with the lid 3. The lid main body 30 can be made of a plastic material, etc., and is configured as a molding of polycarbonate in the present embodiment.

As illustrated in FIG. 6A, etc., the lid main body 30 includes, in its rim portion that faces the sealing face 281 forming part of the opening rim portion 28 of the container main body 2, a sealing member attachment portion 311 and a rim portion facing portion 331. A retaining groove 321 is formed in the sealing member attachment portion 311. The sealing member attachment portion 311 extends all along the rim portion of the lid main body 30, and the retaining groove 321 also extends all along the rim portion of the lid main body 30, along the sealing member attachment portion 311. The rim portion facing portion 331 is constituted of a portion of the rim portion of the lid main body 30 that faces the sealing face 281 forming part of the opening rim portion 28, and that is more outward with respect to the lid 3 than the retaining groove 321. The rim portion facing portion 331 is constituted of a rim portion of the lid main body 30, the rim portion-being a plate-shaped part extending in a D2-D3 plane (which is perpendicular to the forward/backward direction D1).

As illustrated in FIG. 6A, the retaining groove 321 has a groove bottom surface 322 and a pair of groove side surfaces 323. The retaining groove 321 has a substantially rectangular cross section, when cut in a direction perpendicular to the direction in which the retaining groove 321 extends. In this cross section, surfaces extending in the depth direction of the retaining groove 321 from the opening of the retaining groove 321 constitute the pair of the groove side surfaces 323. The groove bottom surface 322 constitutes the bottom of the retaining groove 321. A base portion 41 (to be described later) of the sealing member 4 is inserted into the retaining groove 321. Accordingly, the sealing member 4 is attached to the sealing member attachment portion 311 of the lid 3, and the lip portion 42 of the sealing member 4 can abut on the opening rim portion 28 and the rim portion facing portion 331.

The sealing member 4 is made of various elastically deformable thermoplastic elastomers such as polyester-based elastomers, polyolefin-based elastomers, and the like, fluorine rubber, and silicon rubber, etc. As illustrated in FIG. 4, the sealing member 4 has a rectangular loop shape and is arranged so as to extend all along an outer rim portion of the lid 3.

The sealing member 4 includes the base portion 41 and the lip portion 42. As illustrated in FIGS. 6A and 6C, the base portion 41, when viewed in a direction perpendicular to the circumferential direction of the loop-shaped sealing member 4, has a rectangular cross section whose outer periphery has concavities and convexities. The base portion 41 includes a tip surface 411, a base end 410, and a pair of side surfaces 412 extending from the tip surface 411 to the base end 410. Each of the side surfaces 412 is a concave-convex surface in which concavities and convexities are alternately arranged. The tip surface 411 and the pair of side surfaces 412 of the base portion 41 are inserted into the retaining groove 321. The pair of side surfaces 412 of the base portion 41 inserted into the retaining groove 321 and the pair of groove side surfaces 323 have a positional relationship of facing each other.

The lip portion 42 is integrally formed with the base end 410 to which the side surfaces 412 extend from the tip surface 411 of the base portion 41. The lip portion 42 extends from the base end 410 of the base portion 41 in a direction oblique to the direction in which the side surfaces 412 extend from the tip surface 411 of the base portion 41. As illustrated in FIG. 6A, etc., the lip portion 42 branches halfway into two so as to constitute a rim-portion-abutting lip portion 421 and a facing-portion-abutting lip portion 422. When the container main body opening 21 is closed with the lid 3, the rim-portion-abutting lip portion 421 abuts on the sealing face 281 of the opening rim portion 28 of the container main body 2, and the facing-portion-abutting lip portion 422 abuts on the rim portion facing portion 331.

Here, the portion illustrated in FIG. 6A, which is a portion of the lid 3 located in the upward direction D21, will be described as an example. The rim-portion-abutting lip portion 421 extends in an oblique direction between the backward direction D12 and the upward direction D21 (an outward direction relative to a D2-D3 plane) so as to abut on the opening rim portion 28. The facing-portion-abutting lip portion 422 extends in an oblique direction between the forward direction D11 and the upward direction D21 (an outward direction relative to the D2-D3 plane) so as to abut on the rim portion facing portion 331. Although the direction in which the rim-portion-abutting lip portion 421 extends and the direction in which the facing-portion-abutting lip portion 422 extends differ depending on the position of the sealing member 4 on the lid 3, the directions can generally be referred to as outward directions relative to the D2-D3 plane.

Due to the rim-portion-abutting lip portion 421 abutting on the opening rim portion 28 and the facing-portion-abutting lip portion 422 abutting on the rim portion facing portion 331, the lip portion 42 of the sealing member 4 lies between the opening rim portion 28 and the rim portion facing portion 331 to come into tight contact therewith, and accordingly airtightly closes the container main body opening 21 in cooperation with the lid 3.

Next, the shape of the rim portion facing portion 331 will be described in detail. As illustrated in FIG. 6B, the rim portion facing portion 331 has a cross-sectional shape that is not of a straightly flat plane and indicates a target position PT for the facing-portion-abutting lip portion 422. The rim portion facing portion 331 has the cross-sectional shape that is not of a straightly flat plane all along the rim portion of the lid 3. For example, in the present embodiment, when the base portion 41 of the sealing member 4 is inserted completely into the retaining groove 321 of the sealing member attachment portion 311 of the lid 3 (when the tip surface 411 of the base portion 41 of the sealing member 4 is sufficiently in contact with the groove bottom surface 322 of the retaining groove 321), the sealing member 4 in this state is disposed at the target position PT (see FIGS. 6A and 6B). In this state, airtightness is ensured during the closure with the sealing member 4.

On the other hand, as illustrated in FIG. 6C, when the base portion 41 of the sealing member 4 is not completely inserted into the retaining groove 321 of the sealing member attachment portion 311 of the lid 3, (typically, when the tip surface 411 of the base portion 41 of the sealing member 4 is not in contact with the groove bottom surface 322 of the retaining groove 321), the sealing member 4 in this state is not disposed at (or is deviated from) the target position PT. In this state, airtightness may not be ensured during the closure with the sealing member 4 (the airtightness may not be guaranteed).

As can be seen, it is very important to dispose the sealing member 4 at the target position PT in order to ensure the airtightness during the closure with the sealing member 4. However, it is not easy to check whether the sealing member 4 is disposed at the target position PT on the sealing member attachment portion 311 during the process of manufacturing the lid 3. In addition, from the viewpoint of preventing contamination, it is not practical to provide the sealing member attachment portion 311 of the substrate storing container 1 with marking with an adhesive material for indicating the target position PT, for example.

In contrast, in the present embodiment, the rim portion facing portion 331 has the cross-sectional shape that is not of a straightly flat plane and indicates the target position PT for the facing-portion-abutting lip portion 422. From another perspective, the rim portion facing portion 331 has the plane that is not straightly flat and indicates the target position PT for the facing-portion-abutting lip portion 422, on its side toward the backward direction D12. The cross-sectional shape (plane) that is not straightly flat can indicate the target position PT by means of its shape without marking or the like.

As illustrated in FIG. 6B, the cross-sectional shape of the rim portion facing portion 331 that is not of a straightly flat plane is a protruding shape that protrudes toward the facing-portion-abutting lip portion 422 (in the backward direction D12), with respect to the straightly flat plane (reference plane) P serving as a reference. Typically, the straightly flat plane P as a reference is a straightly flat plane that is assumed hypothetically for the rim portion facing portion 331.

The rim portion facing portion 331 of the first embodiment has a smoothly protruding shape. The top of the protrusion indicates the target position PT. The protrusion may be: a ridge that extends along an entirety of the rim portion of the lid 3 (in the upward/downward direction D2 and the left/right direction D3); a ridge that extends along a part of the rim portion, or a convexity that does not extend substantially.

The substrate storing container 1 of the first embodiment having the above-described configuration exerts the following effects. A substrate storing container 1 of the first embodiment includes: a container main body 2 having therein a substrate storing space 27 that is capable of storing a plurality of substrates W, and having, at one end thereof, an opening rim portion 28 that defines a container main body opening 21 communicating with the substrate storing space 27; and a lid 3 attachable to and detachable from the container main body opening 21, capable of closing the container main body opening 21, and including a sealing member attachment portion 311 and a rim portion facing portion 331 that faces the opening rim portion 28. The lid 3 further includes a sealing member 4 that is attached to the sealing member attachment portion 311 of the lid 3 and lies between the opening rim portion 28 and the rim portion facing portion 331 to come into tight contact therewith, so that the sealing member 4 airtightly closes the container main body opening 21. The sealing member 4 includes a base portion 41 that is retained by the sealing member attachment portion 311, a rim-portion-abutting lip portion 421 that extends from the base portion 41 and abuts on the opening rim portion 28, and a facing-portion-abutting lip portion 422 that extends from the base portion 41 and abuts on the rim portion facing portion 331. The rim portion facing portion 331 has a cross-sectional shape that is not of a straightly flat plane and indicates a target position PT for the facing-portion-abutting lip portion 422.

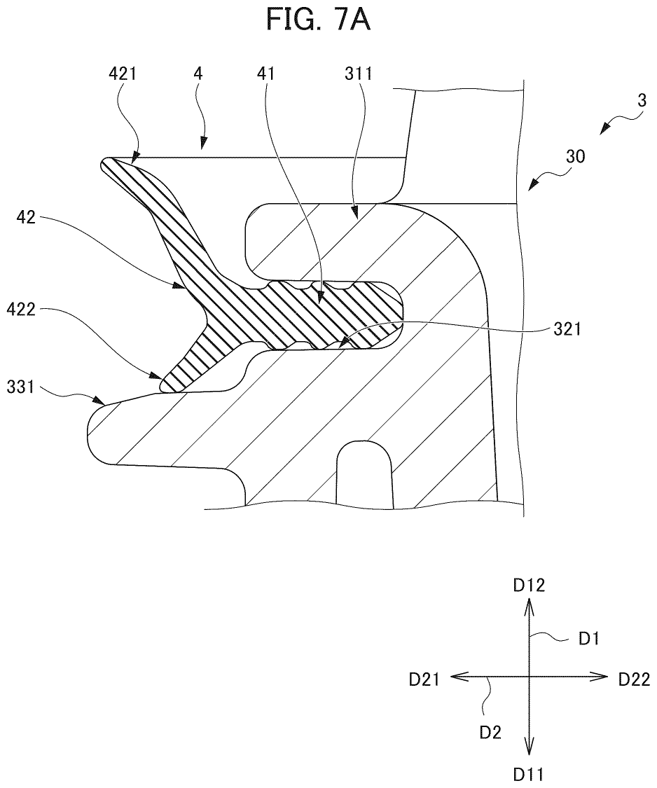

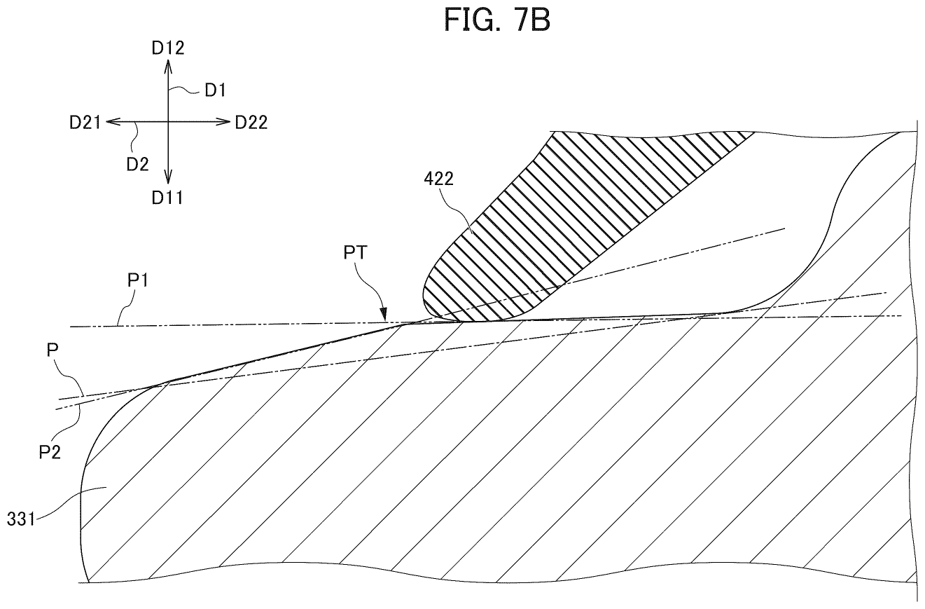

Due to this feature of the first embodiment, the facing-portion-abutting lip portion 422 can be easily disposed at the target position PT, with reference to the shape of the rim portion facing portion 331. There is basically no contamination due to the means for indicating the target position PT.

[Second Embodiment] Next, a second embodiment of the present invention will be described with reference to the drawings. FIG. 7A is a cross-sectional view (corresponding to FIG. 6A) illustrating a lid 3 of a substrate storing container 1 according to the second embodiment of the present invention. FIG. 7B is an enlarged view of a part of FIG. 7A.

As illustrated in FIG. 7A, a rim portion facing portion 331 of the second embodiment has a protruding shape different from that of the first embodiment. Since the configuration of the second embodiment is the same as that of the first embodiment except for the rim portion facing portion 331, the same components are denoted by the same reference numerals, and description thereof is omitted.

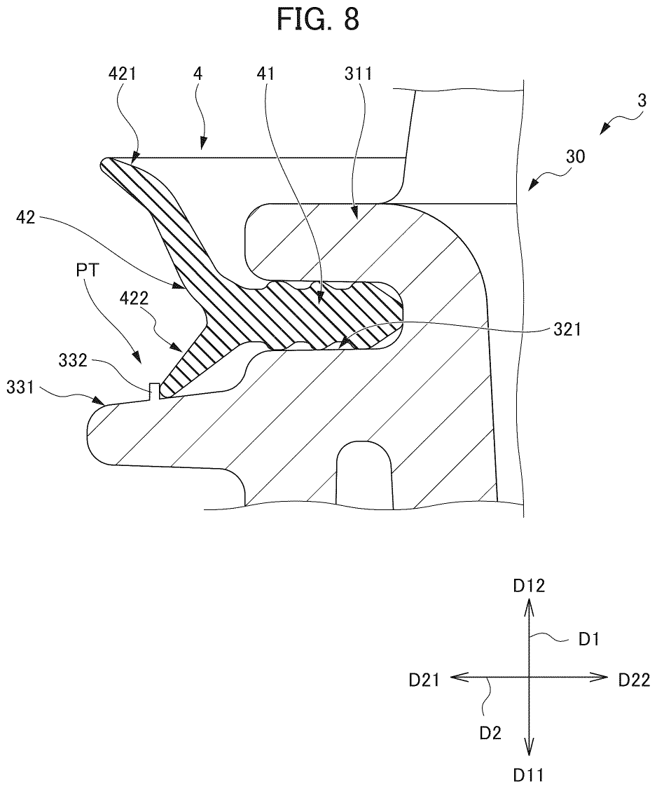

As illustrated in FIGS. 7A and 7B, the protruding shape of the rim portion facing portion 331 of the second embodiment is a shape in which a plurality of straightly flat planes P1 and P2 are connected to each other. A ridge line formed by the plurality of straightly flat planes P1 and P2 indicates a target position PT. The second embodiment exerts the same effects as those of the first embodiment.

[Third Embodiment] Next, a third embodiment of the present invention will be described with reference to the drawings. FIG. 8 is a cross-sectional view (corresponding to FIG. 6A) illustrating a lid 3 of a substrate storing container 1 according to the third embodiment of the present invention.

As illustrated in FIG. 8, a rim portion facing portion 331 of the third embodiment has a protruding shape different from those of the first and second embodiments. Since the configuration of the third embodiment is the same as that of the first embodiment except for the rim portion facing portion 331, the same components are denoted by the same reference numerals, and description thereof is omitted.

As illustrated in FIG. 8, the protruding shape of the rim portion facing portion 331 of the third embodiment is a shape having a projection 332 that locally projects so as to be able to restrict the movement of a facing-portion-abutting lip portion 422.

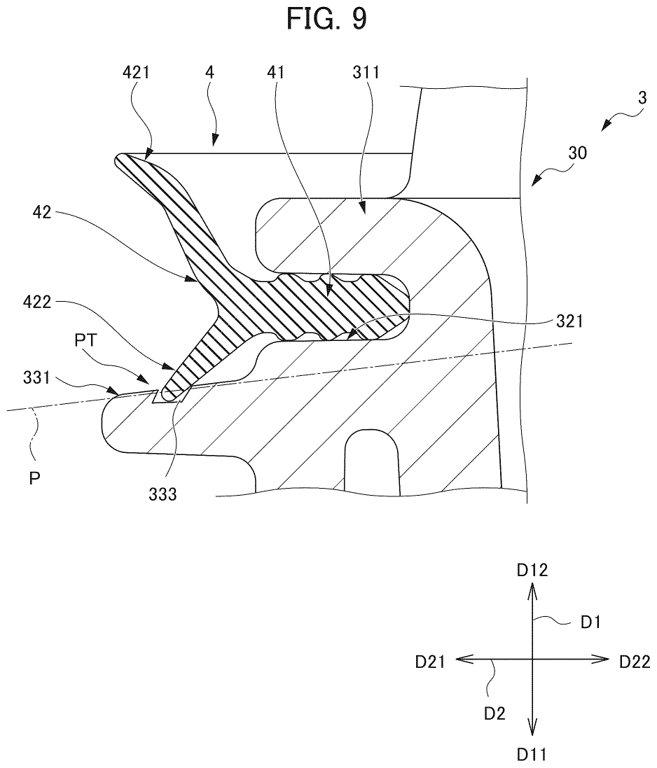

The third embodiment exerts the same effects as those of the first embodiment. Furthermore, according to the third embodiment, since the protruding shape of the rim portion facing portion 331 has the projection 332 that locally projects so as to be able to restrict the movement of the facing-portion-abutting lip portion 422, the facing-portion-abutting lip portion 422 is disposed at the target position PT while abutting against the projection 332. If the facing-portion-abutting lip portion 422 deviates outward from the target position PT, the facing-portion-abutting lip portion 422 does not abut against the projection 332. Thus, it can be easily determined whether or not the facing-portion-abutting lip portion 422 is disposed at the target position PT. Once the facing-portion-abutting lip portion 422 is disposed at the target position PT, the facing-portion-abutting lip portion 422 abuts against the projection 332 and is likely to be caught by the projection 332. Therefore, the state in which the facing-portion-abutting lip portion 422 is disposed at the target position PT is easily maintained.

[Fourth Embodiment] Next, a fourth embodiment of the present invention will be described with reference to the drawings. FIG. 9 is a cross-sectional view (corresponding to FIG. 6A) illustrating a lid 3 of a substrate storing container 1 according to the fourth embodiment of the present invention.

As illustrated in FIG. 9, a rim portion facing portion 331 of the fourth embodiment has a cross-sectional shape that is not of a straightly flat plane and different from those of the first to third embodiments. Since the configuration of the fourth embodiment is the same as that of the first embodiment except for the rim portion facing portion 331, the same components are denoted by the same reference numerals, and description thereof is omitted.

As illustrated in FIG. 9, the cross-sectional shape that is not of a straightly flat plane of the rim portion facing portion 331 of the fourth embodiment has a restricting concavity 333 that caves in to be away from a facing-portion-abutting lip portion 422 (concave in the forward direction D11) with respect to the straightly flat plane P serving as a reference, and that is engageable with the facing-portion-abutting lip portion 422. The restricting concavity 333 may have any shape and size as long as the facing-portion-abutting lip portion 422 can engage with the restricting concavity 333.

The fourth embodiment exerts the same effects as those of the first embodiment. According to the fourth embodiment, the cross-sectional shape that is not of a straightly flat plane of the rim portion facing portion 331 has the restricting concavity 333 that caves in to be away from the facing-portion-abutting lip portion 422 with respect to the straightly flat plane P as a reference, and that is engageable with the facing-portion-abutting lip portion 422. Due to this feature, the facing-portion-abutting lip portion 422 is disposed at the target position PT while being engaged with the restricting concavity 333. If the facing-portion-abutting lip portion 422 deviates outward from the target position PT, the facing-portion-abutting lip portion 422 is not engaged with the restricting concavity 333. Therefore, it can be easily determined whether or not the facing-portion-abutting lip portion 422 is disposed at the target position PT. Once the facing-portion-abutting lip portion 422 is disposed at the target position PT, the facing-portion-abutting lip portion 422 is engaged with the restricting concavity 333, so that the state in which the facing-portion-abutting lip portion 422 is disposed at the target position PT is easily maintained.

The present invention is not limited to the above-described embodiments, and can be modified within the technical scope described in the claims.

For example, in the embodiments, the base portion 41 of the sealing member 4 is retained by the sealing member attachment portion 311 while being inserted in the retaining groove 321. However, this is a non-limiting example of retainment of the base portion 41 by the sealing member attachment portion 311. For example, the base portion 41 of the sealing member 4 may be retained by the sealing member attachment portion 311 through clamping or engagement.

In the embodiments, the rim portion facing portion 331 has the cross-sectional shape that is not of a straightly flat plane all along the rim portion of the lid 3, which is a non-limiting example. The rim portion facing portion 331 may have this cross-sectional shape in a part or a plurality of separate parts in the circumferential direction.

The shape of the container main body 2, the shape of the lid 3, and the number and dimensions of the substrates W that can be stored in the container main body 2 are not limited to those described in the embodiments.

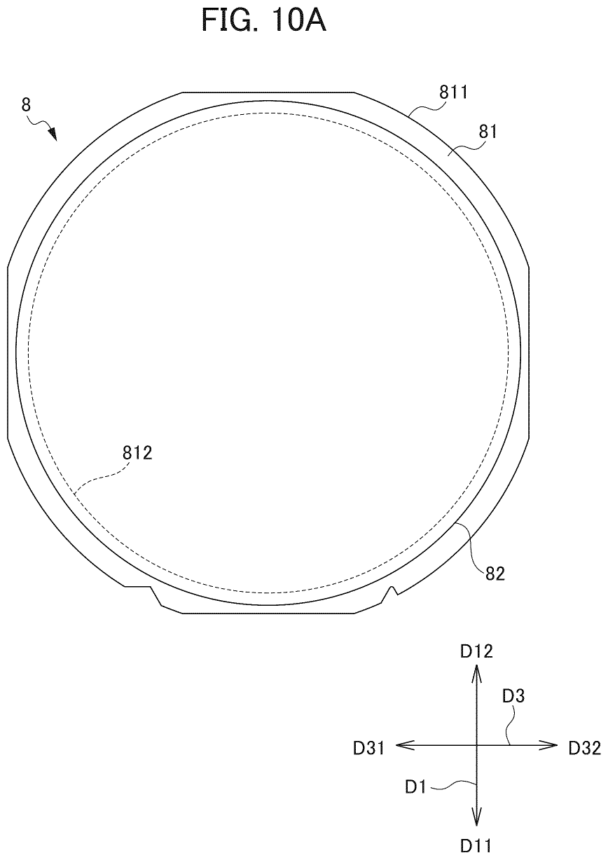

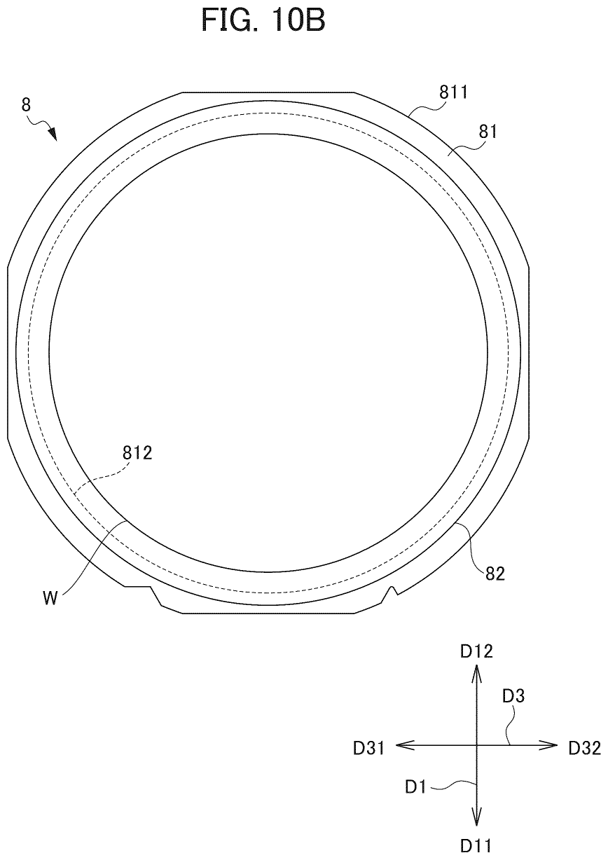

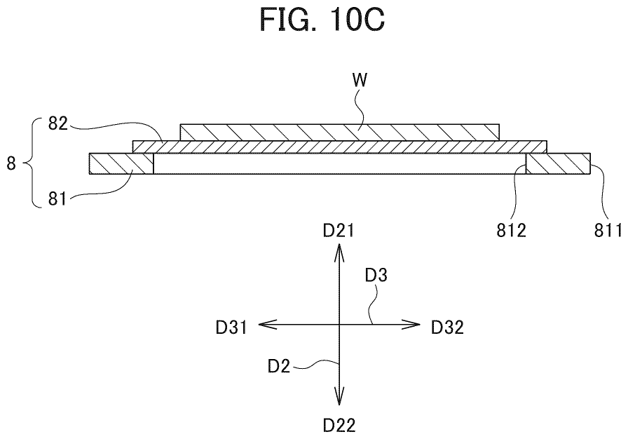

The substrate W can be stored in the substrate storing space 27 with a substrate holding adapter 8. FIG. 10A is a plan view illustrating the substrate holding adapter 8. FIG. 10B is a plan view illustrating a state in which the substrate W is held on the substrate holding adapter 8. FIG. 10C is a schematic longitudinal cross-sectional view taken along the centerline of FIG. 10B. The substrate holding adapter 8 is a member that forms part of the back-side substrate support portion (not shown), the substrate support plate-like portion 5, and the front retainer 7. The substrate holding adapter 8 can also be considered to be a portion extended from the back-side substrate support portion (not shown), the substrate support plate-like portion 5, and the front retainer 7 of the embodiment illustrated in FIGS. 1 to 3 toward the center (center of the substrate W) in a plan view.

As illustrated in FIG. 10A, the substrate holding adapter 8 includes an annular plate-shaped portion 81 and an adhesive sheet 82. The annular plate-shaped portion 81 is made of a plate-shaped member having a substantially o-shape in a plan view (and having an outer circumferential edge 811 and an inner circumferential edge 812 that are substantially circular). The annular plate-shaped portion 81 is made of, for example, metal (e.g., SUS). The adhesive sheet 82 is made of a thin sheet member having adhesiveness, and is attached to the upper surface of the annular plate-shaped portion 81 so as to close a region inside the inner circumferential edge 812 of the annular plate-shaped portion 81. As illustrated in FIGS. 10B and 10C, the adhesive sheet 82 can hold a substrate W with its adhesion. The substrate W is adhered to and held on a region of the adhesive sheet 82 inside the inner circumferential edge 812 of the annular plate-shaped portion 81.

In a case where the substrate holding adapter 8 is applied to the embodiment illustrated in FIGS. 1 to 3, the front-retainer substrate receiving portions 73 of the front retainer 7 support a front portion of an edge portion of the annular plate-shaped portion 81, whereby the substrate holding adapter 8 as a part of the front retainer 7 supports a front portion of an edge portion of the substrate W. Likewise, the substrate holding adapter 8 as a part of the substrate support plate-like portion 5 supports a side portion of the edge portion of the substrate W when the container main body opening 21 is not closed with the lid 3. Likewise, the substrate holding adapter 8 as a part of the back-side substrate support portion (not shown) supports a rear portion of the edge portion of the substrate W when the container main body opening 21 is closed with the lid 3.

When the substrate storing container 1 in which the substrate W is stored receives vibration, impact, or the like, the adhesive sheet 82 reduces the vibration, impact, or the like. Thus, the vibration, impact, or the like is less likely to be transmitted to the substrate W held on the adhesive sheet 82. Therefore, even if the substrate W has a reduced strength due to additional processing following a slicing process, the substrate W stored in the substrate storing container 1 is less likely to be damaged by vibration or impact.

The substrate storing container 1 provided with the substrate holding adapter 8 can be used by being transported or stored in a state in which the substrate holding adapter 8 is disposed in the substrate storing space 27 without storing the substrate W.

The substrate holding adapter 8 is not limited to the annular shape in plan view, and may have an arc shape (not closed).

### EXPLANATION OF REFERENCE NUMERALS

1: Substrate storing container
2: Container main body
3: Lid
4: Sealing member
20: Wall
21: Container main body opening
27: Substrate storing space
28: Opening rim portion
41: Base portion
42: Lip portion
311: Sealing member attachment portion
321: Retaining groove
331: Rim portion facing portion
332: Projection
333: Restricting concavity
421: Rim-portion-abutting lip portion
422: Facing-portion-abutting lip portion
P: Straightly flat plane as reference
P1, P2: A plurality of straightly flat planes
PT: Target position
W: Substrate

1. A substrate storing container comprising:
a container main body having therein a substrate storing space that is capable of storing a plurality of substrates, and having, at one end thereof, an opening rim portion that defines a container main body opening communicating with the substrate storing space; and
a lid attachable to and detachable from the container main body opening, capable of closing the container main body opening, and including a sealing member attachment portion and a rim portion facing portion that faces the opening rim portion, wherein
the lid further includes a sealing member that is attached to the sealing member attachment portion of the lid and lies between the opening rim portion and the rim portion facing portion to come into tight contact therewith, so that the sealing member airtightly closes the container main body opening,
the sealing member includes a base portion that is retained by the sealing member attachment portion, a rim-portion-abutting lip portion that extends from the base portion and abuts on the opening rim portion, and a facing-portion-abutting lip portion that extends from the base portion and abuts on the rim portion facing portion, and
the rim portion facing portion has a cross-sectional shape that is not of a straightly flat plane and indicates a target position for the facing-portion-abutting lip portion.

2. The substrate storing container according to claim 1, wherein
the cross-sectional shape that is not of a straightly flat plane of the rim portion facing portion is a protruding shape that protrudes toward the facing-portion-abutting lip portion with respect to the straightly flat plane serving as a reference.

3. The substrate storing container according to claim 2, wherein
the protruding shape of the rim portion facing portion is a smoothly protruding shape, a shape in which a plurality of straightly flat planes are connected to each other, or a shape having a projection that locally projects so as to be able to restrict a movement of the facing-portion-abutting lip portion.

4. The substrate storing container according to claim 1, wherein
the cross-sectional shape that is not of a straightly flat plane of the rim portion facing portion has a restricting concavity that is concave toward a side away from the facing-portion-abutting lip portion with respect to a straightly flat plane serving as a reference, and that is engageable with the facing-portion-abutting lip portion.

5. The substrate storing container according to claim 1, wherein
the rim portion facing portion has the cross-sectional shape that is not a straightly flat plane all along a rim portion of the lid.

6. A lid of a substrate storing container, the substrate storing container including:
a container main body having therein a substrate storing space that is capable of storing a plurality of substrates, the container main body having, at one end thereof, an opening rim portion that defines a container main body opening communicating with the substrate storing space; and
the lid that is attachable to and detachable from the container main body opening,
the lid comprising:
a sealing member attachment portion and a rim portion facing portion that faces the opening rim portion, so that the lid is capable of closing the container main body opening; and
a sealing member that is attached to the sealing member attachment portion of the lid and lies between the opening rim portion and the rim portion facing portion to come into tight contact therewith, so that the sealing member airtightly closes the container main body opening, wherein
the sealing member includes a base portion that is retained by the sealing member attachment portion, a rim-portion-abutting lip portion that extends from the base portion and abuts on the opening rim portion, and a facing-portion-abutting lip portion that extends from the base portion and abuts on the rim portion facing portion, and
the rim portion facing portion has a cross-sectional shape that is not of a straightly flat plane and indicates a target position for the facing-portion-abutting lip portion.

7. The lid according to claim 6, wherein
the cross-sectional shape that is not of a straightly flat plane of the rim portion facing portion is a protruding shape that protrudes toward the facing-portion-abutting lip portion with respect to the straightly flat plane serving as a reference.

8. The lid according to claim 7, wherein
the protruding shape of the rim portion facing portion is a smoothly protruding shape, a shape in which a plurality of straightly flat planes are connected to each other, or a shape having a projection that locally projects so as to be able to restrict a movement of the facing-portion-abutting lip portion.

9. The lid according to claim 6, wherein
the cross-sectional shape that is not of a straightly flat plane of the rim portion facing portion has a restricting concavity that caves in to be away from the facing-portion-abutting lip portion with respect to the straightly flat plane serving as a reference, and that is engageable with the facing-portion-abutting lip portion.

10. The lid according to claim 6, wherein
the rim portion facing portion has the cross-sectional shape that is not of a straightly flat plane all along a rim portion of the lid.
